(19) United States
(12) Patent Application Publication
(10) Pub. No.: US 2025/0081540 A1
(43) Pub. Date: Mar. 6, 2025

(54) THIN FILM TRANSISTOR AND ELECTRONIC DEVICE

(71) Applicants: Japan Display Inc., Tokyo (JP); IDEMITSU KOSAN CO., LTD., Tokyo (JP)

(72) Inventors: Hajime WATAKABE, Tokyo (JP); Masashi TSUBUKU, Tokyo (JP); Toshinari SASAKI, Tokyo (JP); Takaya TAMARU, Tokyo (JP); Emi KAWASHIMA, Tokyo (JP); Yuki TSURUMA, Tokyo (JP); Daichi SASAKI, Tokyo (JP)

(73) Assignees: Japan Display Inc., Tokyo (JP); IDEMITSU KOSAN CO., LTD., Tokyo (JP)

(21) Appl. No.: 18/950,230

(22) Filed: Nov. 18, 2024

Related U.S. Application Data
(63) Continuation of application No. PCT/JP2023/015626, filed on Apr. 19, 2023.

(30) Foreign Application Priority Data
Jun. 10, 2022 (JP) 2022-094335

(51) Int. Cl. H01L 29/786; H01L 29/04; H01L 29/06; H01L 29/49

(52) U.S. Cl. CPC H10D 30/6756; H10D 30/6739; H10D 62/124; H10D 62/40

(57) ABSTRACT

A thin film transistor includes an oxide semiconductor layer having a polycrystalline structure over a substrate, a gate electrode over the oxide semiconductor layer, and a gate insulating layer between the oxide semiconductor layer and the gate electrode. The oxide semiconductor layer includes a first region having a first carrier concentration and overlapping the gate electrode, a second region having a second carrier concentration and not overlapping the gate electrode, and a third region between the first region and the second region and overlapping the gate electrode. The second carrier concentration is larger than the first carrier concentration. A carrier concentration of the third region decreases from the second region to the first region in a channel length direction. A length of the third region is greater than or equal to 0.00 μm and less than or equal to 0.60 μm in the channel length direction.

### CROSS-REFERENCE TO RELATED APPLICATIONS

This application is a Continuation of International Patent Application No. PCT/JP2023/015626, filed on Apr. 19, 2023, which claims the benefit of priority to Japanese Patent Application No. 2022-094335, filed on Jun. 10, 2022, the entire contents of each are incorporated herein by reference.

### FIELD

An embodiment of the present invention relates to a thin film transistor including an oxide semiconductor having a polycrystalline structure (Poly-OS). Further, an embodiment of the present invention relates to an electronic device including the thin film transistor.

### BACKGROUND

In recent years, instead of a silicon semiconductor film using amorphous silicon, low-temperature polysilicon, and single-crystal silicon, a thin film transistor in which an oxide semiconductor film is used for a channel has been developed (for example, see Japanese laid-open patent publication Nos. 2021-141338, 2014-099601, 2021-153196, 2018-006730, 2016-184771, and 2021-108405). The thin film transistor including an oxide semiconductor film can be manufactured with a simple structure and low-temperature process, similar to a thin film transistor including an amorphous silicon film. Further, the thin film transistor including an oxide semiconductor film is known to have a higher field-effect mobility than the thin film transistor including an amorphous silicon film.

### SUMMARY

A thin film transistor according to an embodiment of the present invention includes an oxide semiconductor layer having a polycrystalline structure over a substrate, a gate electrode over the oxide semiconductor layer, and a gate insulating layer between the oxide semiconductor layer and the gate electrode. The oxide semiconductor layer includes a first region having a first carrier concentration and overlapping the gate electrode, a second region having a second carrier concentration and not overlapping the gate electrode, and a third region between the first region and the second region and overlapping the gate electrode. The second carrier concentration is larger than the first carrier concentration. A carrier concentration of the third region decreases from the second region to the first region in a channel length direction. A length of the third region is greater than or equal to 0.00 μm and less than or equal to 0.60 μm in the channel length direction.

An electronic device according to an embodiment of the present invention includes the thin film transistor.

### BRIEF DESCRIPTION OF DRAWINGS

FIG. 1 is a schematic cross-sectional view showing a configuration of a thin film transistor according to an embodiment of the present invention.

FIG. 2 is a schematic plan view showing a configuration of a thin film transistor according to an embodiment of the present invention.

FIG. 3 is a schematic diagram illustrating a carrier concentration in an oxide semiconductor layer of a thin film transistor according to an embodiment of the present invention.

FIG. 4 is a schematic diagram illustrating an SCM observation of a thin film transistor according to an embodiment of the present invention.

FIG. 5 is a schematic cross-sectional view showing a configuration of a thin film transistor according to an embodiment of the present invention.

FIG. 6 is a flowchart showing a method for manufacturing a thin film transistor according to an embodiment of the present invention.

FIG. 7 is a schematic cross-sectional view showing a method for manufacturing a thin film transistor according to an embodiment of the present invention.

FIG. 8 is a schematic cross-sectional view showing a method for manufacturing a thin film transistor according to an embodiment of the present invention.

FIG. 9 is a schematic cross-sectional view showing a method for manufacturing a thin film transistor according to an embodiment of the present invention.

FIG. 10 is a schematic cross-sectional view showing a method for manufacturing a thin film transistor according to an embodiment of the present invention.

FIG. 11 is a schematic cross-sectional view showing a method for manufacturing a thin film transistor according to an embodiment of the present invention.

FIG. 12 is a schematic cross-sectional view showing a method for manufacturing a thin film transistor according to an embodiment of the present invention.

FIG. 13 is a schematic cross-sectional view showing a method for manufacturing a thin film transistor according to an embodiment of the present invention.

FIG. 14 is a schematic diagram showing an electronic device according to an embodiment of the present invention.

FIG. 15A shows graphs showing electrical characteristics of Example Sample 1 and Comparative Example Sample 1.

FIG. 15B shows graphs showing electrical characteristics of Example Sample 1 and Comparative Example Sample 1.

FIG. 15C shows graphs showing electrical characteristics of Example Sample 1 and Comparative Example Sample 1.

FIG. 16 is a graph showing a result of TDS measurements for Example Sample 2 and Comparative Example Sample 2.

FIG. 17 is a graph showing a result of an SCM observation of Example Sample 1.

FIG. 18A is a graph in which a ΔC/ΔV signal obtained by an SCM observation of Example Sample 1 is fitted with a Gaussian function.

FIG. 18B is a graph in which a ΔC/ΔV signal obtained by an SCM observation of Example Sample 1 is fitted with a complementary error function.

FIG. 18C is a graph in which a ΔC/ΔV signal obtained by an SCM observation of Example Sample 1 is fitted with a Lorentz function.

FIG. 19 is a graph showing a result of an SCM observation of Example Sample 3.

FIG. 20A is a graph in which a ΔC/ΔV signal obtained by an SCM observation of Example Sample 3 is fitted with a Gaussian function.

FIG. 20B is a graph in which a ΔC/ΔV signal obtained by an SCM observation of Example Sample 3 is fitted with a complementary error function.

FIG. 20C is a graph in which a ΔC/ΔV signal obtained by an SCM observation of Example Sample 3 is fitted with a Lorentz function.

### DESCRIPTION OF EMBODIMENTS

In a conventional thin film transistor including an oxide semiconductor, when the channel length is reduced, the threshold voltage shifts in the negative direction or the variation in the threshold voltage increases. In other words, it is difficult to obtain stable electrical characteristics in the conventional thin film transistor including an oxide semiconductor. Therefore, in the conventional thin film transistor including an oxide semiconductor, the degree of freedom in designing the channel length is low, and the applications of the thin film transistor may be limited in some cases.

In view of the above problems, an embodiment of the present invention can provide a thin film transistor including an oxide semiconductor having a high degree of freedom in designing a channel length. Further, an embodiment of the present invention can provide an electronic device including the thin film transistor.

Hereinafter, embodiments of the present invention are described with reference to the drawings. The following invention is merely an example. A configuration that can be easily conceived by a person skilled in the art by appropriately changing the configuration of the embodiment while keeping the gist of the invention is naturally included in the scope of the present invention. In order to make the description clearer, the drawings may schematically show the widths, thicknesses, shapes, and the like of components in comparison with the actual embodiments. However, the illustrated shapes are merely examples, and do not limit the interpretation of the present invention. In the present specification and the drawings, the same reference signs are given to components similar to those described previously with respect to the above-described drawings, and detailed description thereof may be omitted as appropriate.

In the present specification and the like, a direction from a substrate toward an oxide semiconductor layer is referred to as “on” or “over” in each embodiment of the present invention. Conversely, a direction from the oxide semiconductor layer to the substrate is referred to as “under” or “below.” For convenience of explanation, the phrase “over” or “below” is used for description, but for example, the substrate and the oxide semiconductor layer may be arranged so that the vertical relationship is reversed from that shown in the drawings. Further, the expression “an oxide semiconductor layer on a substrate” merely describes the vertical relationship between the substrate and the oxide semiconductor layer as described above, and another member may be arranged between the substrate and the oxide semiconductor layer. The terms “over” or “below” mean a stacking order in which a plurality of layers is stacked, and may have a positional relationship in which a thin film transistor and a pixel electrode do not overlap in a plan view when expressed as “a pixel electrode over a thin film transistor.” On the other hand, the expression “a pixel electrode vertically over a thin film transistor” means a positional relationship in which the thin film transistor and the pixel electrode overlap in a plan view. In addition, a plan view refers to viewing from a direction perpendicular to a surface of the substrate.

In the present specification and the like, the terms “film” and “layer” can be optionally interchanged with one another.

In the present specification and the like, a “display device” refers to a structure that displays an image using an electro-optic layer. For example, the term “display device” may refer to a display panel that includes the electro-optic layer, or may refer to a structure with other optical members (for example, a polarized member, a backlight, a touch panel, and the like) attached to a display cell. The “electro-optic layer” may include a liquid crystal layer, an electroluminescent (EL) layer, an electrochromic (EC) layer, or an electrophoretic layer, as long as there is no technical contradiction. Therefore, although a liquid crystal display device including a liquid crystal layer and an organic EL display device including an organic EL layer are exemplified as a display device in the following embodiments, the structure according to the present embodiment can be applied to a display device including the other electro-optic layers described above.

In the present specification and the like, the expression “a includes A, B, or C,” “a includes any of A, B, or C,” “a includes one selected from a group consisting of A, B and C,” and the like does not exclude the case where a includes a plurality of combinations of A to C unless otherwise specified. Further, these expressions do not exclude the case where a includes other components.

In addition, the following embodiments can be combined with each other as long as there is no technical contradiction.

### First Embodiment

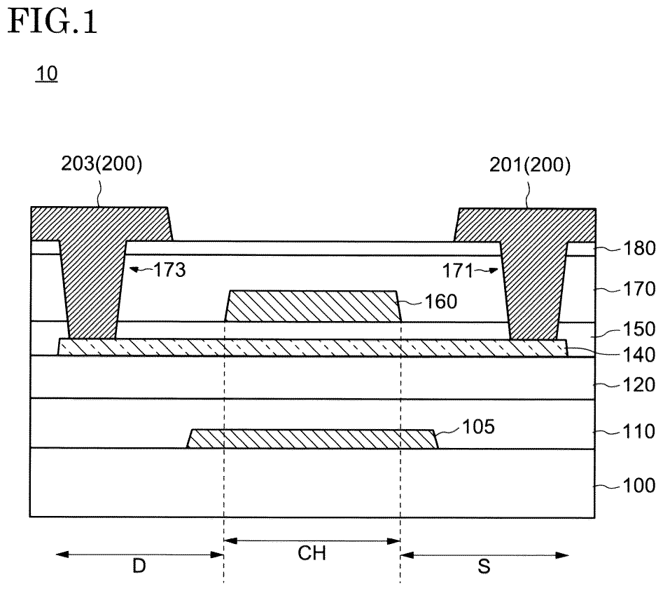

A thin film transistor 10 according to an embodiment of the present invention is described with reference to FIGS. 1 to 13. For example, the thin film transistor 10 may be used in an integrated circuit (IC) such as a micro-processing unit (MPU) or a memory circuit in addition to a transistor used in a display device.

### [1. Configuration of Thin Film Transistor 10]

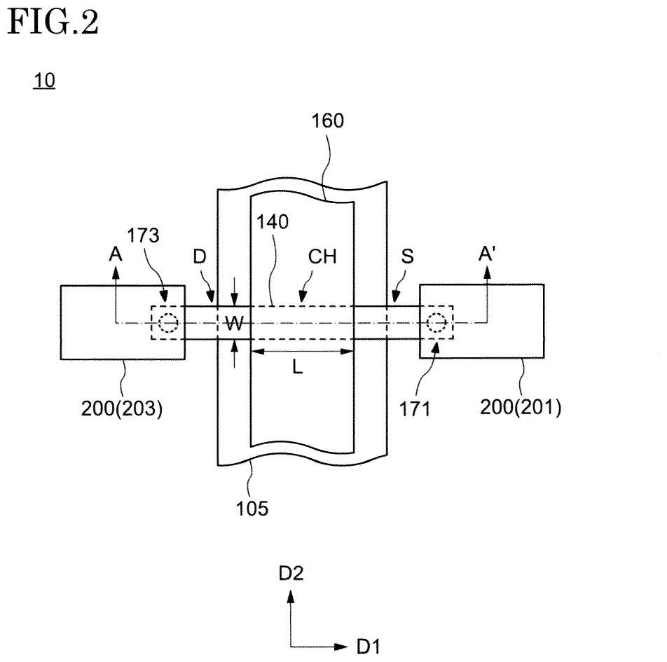

A configuration of a thin film transistor 10 according to an embodiment of the present invention is described with reference to FIGS. 1 and 2. FIG. 1 is a schematic cross-sectional view showing the configuration of the thin film transistor 10 according to an embodiment of the present invention. FIG. 2 is a schematic plan view showing the configuration of the thin film transistor 10 according to an embodiment of the present invention. Specifically, FIG. 1 is a cross-sectional view cut along line A-A′ in FIG. 2.

As shown in FIG. 1, the thin film transistor 10 includes a substrate 100, a light shielding layer 105, a first insulating layer 110, a second insulating layer 120, an oxide semiconductor layer 140, a gate insulating layer 150, a gate electrode 160, a third insulating layer 170, a fourth insulating layer 180, a source electrode 201, and a drain electrode 203. The light shielding layer 105 is provided on the substrate 100. The first insulating layer 110 is provided on the substrate 100 so as to cover an upper surface and an edge surface of the light shielding layer 105. The second insulating layer 120 is provided on the first insulating layer 110. The oxide semiconductor layer 140 is provided on the second insulating layer 120. The gate insulating layer 150 is provided on the second insulating layer 120 so as to cover an upper surface and an edge surface of the oxide semiconductor layer 140. The gate electrode 160 is provided on the gate insulating layer 150 so as to overlap the oxide semiconductor layer 140. The third insulating layer 170 is provided on the gate insulating layer 150 so as to cover an upper surface and an edge surface of the gate electrode 160. The fourth insulating layer 180 is provided on the third insulating layer 170. The gate insulating layer 150, the third insulating layer 170, and the fourth insulating layer 180 are provided with openings 171 and 173 through which a part of the upper surface of the oxide semiconductor layer 140 is exposed. The source electrode 201 is provided on the fourth insulating layer 180 and inside the opening 171, and is in contact with the oxide semiconductor layer 140. Similarly, the drain electrode 203 is provided on the fourth insulating layer 180 and inside the opening 173, and is in contact with the oxide semiconductor layer 140. In the following description, when the source electrode 201 and the drain electrode 203 are not particularly distinguished from each other, they may be collectively referred to as a source-drain electrode 200.

The oxide semiconductor layer 140 is divided into a source area S, a drain area D, and a channel area CH based on the gate electrode 160. That is, the oxide semiconductor layer includes the channel region CH which overlaps the gate electrode 160 and the source region S and the drain region D which do not overlap the gate electrode 160. In a thickness direction of the oxide semiconductor layer 140, an edge portion of the channel region CH is substantially aligned with an edge portion of the gate electrode 160. The channel region CH has properties of a semiconductor. Each of the source region S and the drain region D has properties of a conductor. Therefore, the electrical conductivities of the source region S and the drain region D are larger than the electrical conductivity of the channel region CH. The source electrode 201 and the drain electrode 203 are in contact with the source region S and the drain region D, respectively, and are electrically connected to the oxide semiconductor layer 140. Further, the oxide semiconductor layer 140 may have a single layer structure or a laminated structure.

As shown in FIG. 2, each of the light shielding layer 105 and the gate electrode 160 has a predetermined width in a direction D1 and extends in a direction D2 orthogonal to the direction D1. A width of the light shielding layer 105 is greater than a width of the gate electrode 160 in the direction D1. The channel region CH completely overlaps the light shielding layer 105. In the semiconductor device 10, the direction D1 corresponds to the direction in which a current flows from the source electrode 201 to the drain electrode 203 through the oxide semiconductor layer 140. Therefore, a length of the channel region CH in the direction D1 is a channel length L, and a width of the channel region CH in the direction D2 is a channel width W.

The substrate 100 can support each layer in the thin film transistor 10. For example, a rigid substrate with translucency such as a glass substrate, a quartz substrate, or a sapphire substrate can be used as the substrate 100. Further, a rigid substrate without translucency such as a silicon substrate can be used as the substrate 100. Furthermore, a flexible substrate with translucency such as a polyimide resin substrate, an acrylic resin substrate, a siloxane resin substrate, or a fluorine resin substrate can be used as the substrate 100. In order to improve the heat resistance of the substrate 100, impurities may be introduced into the resin substrate. In addition, a substrate in which a silicon oxide film or a silicon nitride film is formed over the rigid substrate or the flexible substrate described above can be used as the substrate 100.

The light shielding layer 105 can reflect or absorb external light. As described above, since the light shielding layer 105 has a larger area than the channel region CH of the oxide semiconductor layer 140, the light shielding layer 105 can block external light entering the channel region CH. For example, aluminum (Al), copper (Cu), titanium (Ti), molybdenum (Mo), tungsten (W), or alloys or compounds thereof can be used for the light shielding layer 105.

Further, the light shielding layer 105 may not necessarily include a metal when conductivity of the light shielding layer 105 is not required. For example, a black matrix made of black resin can be used for the light shielding layer 105. Furthermore, the light shielding layer 105 may have a single layer structure or a laminated structure. For example, the light shielding layer 105 may have a laminated structure of a red color filter, a green color filter, and a blue color filter.

The first insulating layer 110, the second insulating layer 120, the third insulating layer 170, and the fourth insulating layer 180 can prevent impurities from diffusing into the oxide semiconductor layer 140. Specifically, the first insulating layer 110 and the second insulating layer 120 can prevent diffusion of impurities contained in the substrate 100, and the third insulating layer 170 and the fourth insulating layer 180 can prevent diffusion of impurities (for example, water) entering from the outside. For example, silicon oxide (SiOₓ), silicon oxynitride (SiOₓN_{y}), silicon nitride (SiNₓ), silicon nitride oxide (SiNₓO_{y}), aluminum oxide (AlOₓ), aluminum oxynitride (AlOₓN_{y}), aluminum nitride oxide (AlNₓO_{y}), or aluminum nitride (AlNₓ) and the like are used for each of the first insulating layer 110, the second insulating layer 120, the third insulating layer 170, and the fourth insulating layer 180. Here, silicon oxynitride (SiOₓN_{y}) and aluminum oxynitride (AlOₓN_{y}) are a silicon compound and an aluminum compound, respectively, that contain a smaller proportion (x>y) of nitrogen (N) than oxygen (O). Silicon nitride oxide (SiNₓO_{y}) and aluminum nitride oxide (AlNₓO_{y}) are a silicon compound and an aluminum compound, respectively, that contain a smaller proportion (x>y) of oxygen than nitrogen. Further, each of the first insulating layer 110, the second insulating layer 120, the third insulating layer 170, and the fourth insulating layer 180 may have a single layer structure or a laminated structure.

Further, each of the first insulating layer 110, the second insulating layer 120, the third insulating layer 170, and the fourth insulating layer 180 may have a planarization function or a function of releasing oxygen by a heat treatment. For example, when the second insulating layer 120 has a function of releasing oxygen by a heat treatment, oxygen is released from the second insulating layer 120 by the heat treatment performed in the manufacturing process of the thin film transistor 10, and the released oxygen can be supplied to the oxide semiconductor layer 140.

The gate electrode 160, the source electrode 201, and the drain electrode 203 are conductive. For example, copper (Cu), aluminum (Al), titanium (Ti), chromium (Cr), cobalt (Co), nickel (Ni), molybdenum (Mo), hafnium (Hf), tantalum (Ta), tungsten (W), or bismuth (Bi), or alloys or compounds thereof can be used for each of the gate electrode 160, the source electrode 201, and the drain electrode 203. Each of the gate electrode 160, source electrode 201, and drain electrode 203 may have a single layer structure or a laminated structure.

The gate insulating layer 150 includes an oxide having insulating properties. Specifically, silicon oxide (SiOₓ), silicon oxynitride (SiOₓN_{y}), aluminum oxide (AlOₓ), aluminum oxynitride (AlOₓN_{y}), or the like is used for the gate insulating layer 150. The gate insulating layer 150 preferably has a composition close to the stoichiometric ratio. Further, the gate insulating layer 150 preferably has few defects. For example, an oxide in which few defects are observed when evaluated by electron spin resonance (ESR) may be used for the gate insulating layer 150.

The oxide semiconductor layer 140 has a polycrystalline structure including multiple crystal grains. Although the details are described later, the oxide semiconductor layer 140 having a polycrystalline structure can be formed by using a Poly-OS (Poly-crystalline Oxide Semiconductor) technology. Although the structure of the oxide semiconductor layer 140 is described below, an oxide semiconductor having a polycrystalline structure may be referred to as a Poly-OS.

### [2. Configuration of Oxide Semiconductor Layer 140]

### [2-1. Composition Ratio of Oxide Semiconductor Layer 140]

An oxide semiconductor containing indium (In) and a metal element (M) other than indium is used for the oxide semiconductor layer 140. It is preferable that the atomic ratio of indium and the metal element other than indium in the composition ratio of the oxide semiconductor layer 140 satisfies formula (1). In other words, it is preferable that the ratio of indium to all metal elements in the oxide semiconductor layer 140 is greater than or equal to 50%.

$$\begin{matrix}[ Equation 1 ] & \\ 0.01 < \frac{[ M ]}{[ ln ] + [ M ]} < 0.5 & ( 1 )\end{matrix}$$

The metal element other than indium is not limited to one type of metal element. A plurality of types of metal elements may be contained in the oxide semiconductor layer 140 as the metal elements other than indium (hereinafter, referred to as “other metal elements”). Although details of a method for manufacturing the oxide semiconductor layer 140 are described later, the oxide semiconductor layer 140 can be formed by a sputtering method. The composition of the oxide semiconductor layer 140 formed by the sputtering method depends on the composition of the sputtering target. When the sputtering target has the above-described composition, the oxide semiconductor layer 140 without composition deviation of the metal elements can be formed by the sputtering method. Therefore, the composition of the metal elements (e.g., indium and other metal elements) of the oxide semiconductor layer 140 may be equivalent to the composition of the metal elements of the sputtering target. For example, the composition of the metal elements of the oxide semiconductor layer 140 can be specified based on the composition of the metal elements of the sputtering target. In addition, oxygen contained in the oxide semiconductor layer 140 is not limited thereto because it changes depending on the process conditions of the sputtering method.

Further, the composition of the metal elements in the oxide semiconductor layer 140 can be specified by X-ray fluorescence analysis, EPMA (Electron Probe Micro Analyzer) analysis, or the like. Furthermore, the composition of the metal elements in the oxide semiconductor layer 140 can be specified based on the crystal structure and lattice constant of the oxide semiconductor layer 140 by X-ray diffraction (XRD).

### [2-2. Crystal Structure of Oxide Semiconductor Layer 140]

The oxide semiconductor layer 140 includes a Poly-OS. The crystal grain size of the crystal grain included in the Poly-OS observed from the upper surface of the oxide semiconductor layer 140 (or from the thickness direction of the oxide semiconductor layer 140) is greater than or equal to 0.1 μm, preferably greater than or equal to 0.3 μm, and more preferably greater than or equal to 0.5 μm. The crystal grain size of the crystal grain can be obtained by, for example, cross-sectional SEM observation, cross-sectional TEM observation, or an electron back scattered diffraction (EBSD) method.

The crystal grain contained in the oxide semiconductor layer 140 may be composed of a plurality of crystallites. Although the crystallite size is not limited to a particular size, the crystallite size is preferably greater than or equal to 1 nm, more preferably greater than or equal to 10 nm, and further preferably greater than or equal to 10 nm. The crystallite size can be obtained by an electron beam diffraction method, an XRD method, or the like.

In the Poly-OS, a plurality of crystal grains may have one type of crystal structure, or may have a plurality of types of crystal structures. The crystal structure of the Poly-OS can be specified using an electron diffraction method, an XRD method, or the like. That is, the crystal structure of the oxide semiconductor layer 140 can be specified using the electron diffraction method, the XRD method, or the like.

Although the crystal structure of the oxide semiconductor layer 140 is not limited to a particular structure, it is preferable that the oxide semiconductor layer 140 has a bixbyite structure. When the ratio of indium increases as described above, the crystal structure of each of the plurality of crystal grains is controlled, so that the oxide semiconductor layer 140 having the bixbyite structure can be formed.

### [2-3. Carrier Concentration of Oxide Semiconductor Layer 140]

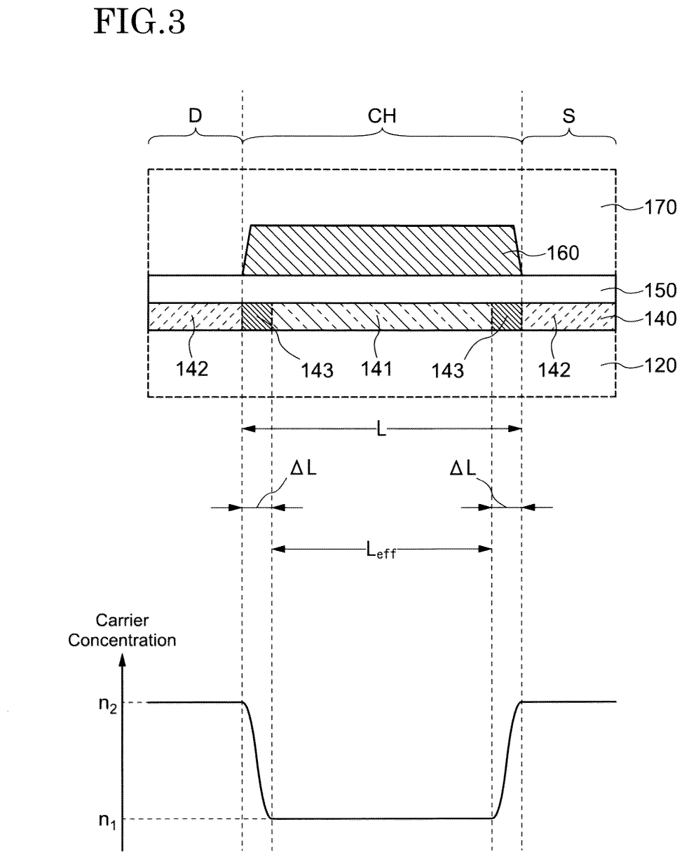

FIG. 3 is a schematic diagram illustrating a carrier concentration in the oxide semiconductor layer 140 of the thin film transistor 10 according to an embodiment of the present invention.

As described above, the oxide semiconductor layer 140 is defined as a source region S, a drain region D, and a channel region CH. The source region S and the drain region D are so-called n+ regions in which, for example, argon (Ar), phosphorus (P), or boron (B) is contained as an impurity. Therefore, the carrier concentration of each of the source region S and the drain region D is higher than that of the channel region CH. The first region 141 included in the channel region CH has a first carrier concentration n₁. The second region 142 included in each of the source region S and the drain region D has a second carrier concentration n₂ higher than the first carrier concentration n₁. In the oxide semiconductor layer 140, the change from the second carrier concentration n₂ of the second region 142 to the first carrier concentration n₁ of the first region 141 is not discontinuous, and a third region 143 having a carrier concentration gradient exists between the second region 142 and the first region 141. That is, the third region 143 has a carrier concentration that decreases from the second carrier concentration n₂ to the first carrier concentration n₁ (or increases from the first carrier concentration n₁ to the second carrier concentration n₂).

The third region 143 is included in the channel region CH, and one edge portion of the third region 143 is substantially aligned with the edge portion of the channel region CH. That is, in the film thickness direction of the oxide semiconductor layer 140, one edge portion of the third region 143 is substantially aligned with the edge portion of the gate electrode 160. However, since the third region 143 has a higher carrier concentration than the first region 141, the properties of the third region 143 are closer to a conductor than a semiconductor. Therefore, when the third region 143 exists, a region that functions as a channel in the channel region CH becomes smaller, and the substantial channel length (hereinafter, referred to as “effective channel length L_{eff}”) becomes smaller than the channel length L defined as the length of the channel region CH. When the length of the third region 143 in the channel length direction (hereinafter, referred to as “penetration length”) is ΔL, the effective channel length L_{eff} is expressed by formula (2).

$$\begin{matrix}[ Equation 2 ] & \\ {L}_{e f f} = L - 2 Δ L & ( 2 )\end{matrix}$$

As can be seen from formula (2), when the penetration length ΔL increases, the effective channel length L_{eff} decreases, and the oxide semiconductor layer 140 does not function as a channel. Further, even when the channel length L is reduced by design, the penetration length ΔL hardly changes. Therefore, it is very important that the penetration length ΔL is small in the thin film transistor 10 having a small channel length L. The penetration length ΔL of the thin film transistor 10 is smaller than that of a conventional thin film transistor. The penetration length ΔL in the thin film transistor 10 is greater than or equal to 0.00 μm and less than or equal to 0.60 μm, preferably greater than or equal to 0.00 μm and less than or equal to 0.50 μm, more preferably greater than or equal to 0.00 μm and less than or equal to 0.40 μm, and particularly preferably greater than or equal to 0.00 μm and less than or equal to 0.30 μm. For example, in the thin film transistor 10 having a channel length L of 2 μm, when the penetration length ΔL is less than or equal to 0.60 μm, the effective channel length L_{eff} which is larger than the penetration length ΔL can be ensured.

The third region 143 is formed by diffusion of hydrogen from the second region 142. Therefore, the penetration length ΔL of the third region 143 depends on the diffusion coefficient of hydrogen in the oxide semiconductor layer 140. The Poly-OS included in the oxide semiconductor layer 140 has a small diffusion coefficient of hydrogen and can suppress diffusion of hydrogen. Therefore, in the thin film transistor 10, the penetration length ΔL of the third region 143 can be controlled to be within the above range.

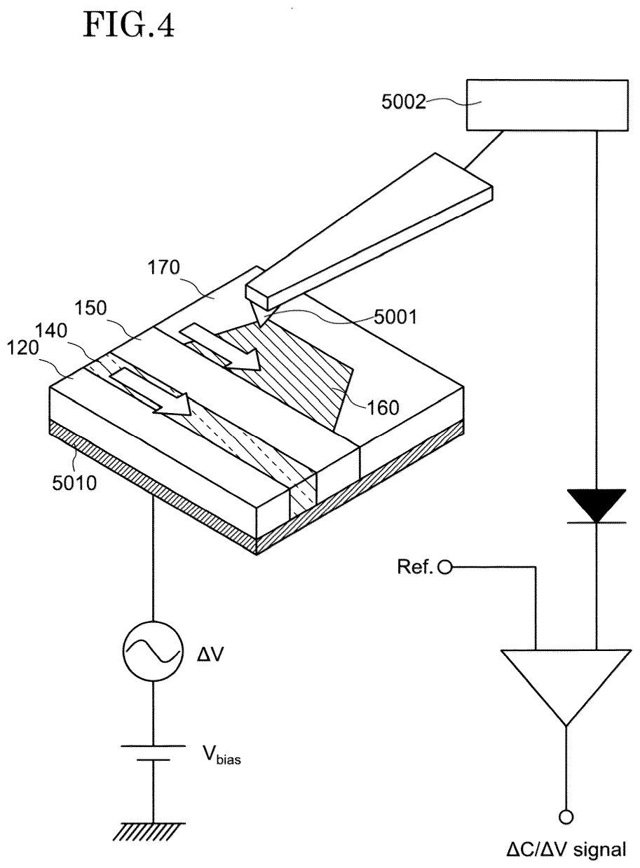

The third region 143 is a region in which the carrier concentration decreases in the channel length direction from the second region 142 to the first region 141. Therefore, the penetration length ΔL of the third region 143 can be obtained by measuring the change in the carrier concentration in the oxide semiconductor layer 140. The carrier concentration in the oxide semiconductor layer 140 can be measured using a scanning spreading resistance microscope (SSRM) or a scanning capacitance microscope (SCM). Hereinafter, an SCM observation is described with reference to FIG. 4.

FIG. 4 is a schematic diagram illustrating an SCM observation of the thin film transistor 10 according to an embodiment of the present invention.

In an SCM observation of the thin film transistor 10, a sample in which the cross section of the thin film transistor 10 is sliced is used. Further, a conductive film such as platinum (Pt) is deposited on the first surface of the sample. The SCM observation basically uses the same device configuration as the atomic force microscope (AFM) observation. Therefore, it is possible to perform not only an SCM observation but also an AFM observation. In the SCM observation, a conductive probe 5001 is placed in contact with the second surface opposite to the first surface of the sample. At this time, since a minute capacitor is formed between the probe 5001 and the sample, a modulation voltage (AC voltage) ΔV is applied to the conductive film on the first surface of the sample, and a capacitance change ΔC is detected by a UHF capacitance sensor 5002 connected to the probe 5001. Therefore, a ΔC/ΔV signal in the scanning direction can be obtained by scanning the probe 5001 on the second surface of the sample.

The frequency of the modulation voltage ΔV is, for example, 100 kHz, and the frequency of the UHF capacitance sensor is, for example, 1 GHZ. Further, a DC bias voltage V_{bias} may be applied to the modulation voltage ΔV.

When the carrier concentration of the oxide semiconductor layer 140 is large, the absolute value of the electrostatic capacitance is small. On the other hand, when the carrier concentration of the oxide semiconductor layer 140 is small, the absolute value of the electrostatic capacitance is large. That is, the change in the carrier concentration in the oxide semiconductor layer 140 corresponds to the change in the ΔC/ΔV signal. Therefore, in the SCM observation of the thin film transistor 10, when the probe 5001 is scanned in the channel length direction on the oxide semiconductor layer 140 to detect the change in the carrier concentration of the oxide semiconductor layer 140 from the ΔC/ΔV signal, the third region 143 can be specified. The penetration length ΔL is calculated based on the specified third region 143.

In the AFM observation, when the probe 5001 is scanned in the channel length direction so as to pass through the edge portion of the gate electrode 160, the edge portion of the gate electrode 160 can be detected. Therefore, when the AFM observation is performed along with the SCM observation, the edge portion of the channel region CH can be detected. In this case, the third region 143 may be specified by assuming that the edge portion of the third region 143 on the side of the second region 142 is substantially aligned with the edge portion of the gate electrode 160 to calculate the penetration length ΔL.

The penetration depth ΔL of the third region 143 may be calculated using a fitting function. As described above, the third region 143 is formed by the diffusion of hydrogen. Since the diffusion of hydrogen in the third region 143 is considered to have a Gaussian distribution, the curve f(x) of the ΔC/ΔV signal can be fitted using a Gaussian function formula (3)) or a complementary error function (formula (4)).

$$\begin{matrix}[ Equation 3 ] & \\ f ( x ) = A exp \{ - \frac{{( x - b )}^{2}}{2 {c}^{2}} \} & ( 3 )\end{matrix}$$

$$\begin{matrix}[ Equation 4 ] & \\ f ( x ) = A erfc \{ \frac{( x - b )}{2 c} \} & ( 4 )\end{matrix}$$

In formulas (3) and (4), the value A is the amplitude of the change in the ΔC/ΔV signal, the value b is the offset value, and the value c is the scale parameter. The penetration depth ΔL can be calculated based on the value c. For example, in the case of the Gaussian function, the distance at which the ΔC/ΔV signal changes by about 99.7% can be expressed as 3c. That is, when fitting using the Gaussian function, most of the penetration depth ΔL of the third region 143 can be covered by using ΔL=3c. The same calculation applies to the complementary error function. Therefore, when a fitting function is used, the penetration depth ΔL of the third region 143 can be calculated as ΔL=3c.

The formation of the third region 143 in the channel region CH may be due to factors other than hydrogen diffusion (e.g., oxygen defects, etc.). Therefore, the fitting function of the ΔC/ΔV signal is not limited to the Gaussian function and the complementary error function. For example, a Lorentz function (formula (5)) may be used as the fitting function.

$$\begin{matrix}[ Equation 5 ] & \\ f ( x ) = A \frac{{c}^{2}}{{( x - b )}^{2} + {c}^{2}} & ( 5 )\end{matrix}$$

In formula (5), A is the amplitude of the change in the ΔC/ΔV signal, b is the offset value, and c is the half-width at half maximum. In this case, the penetration depth ΔL of the third region 143 may be calculated as ΔL=3c.

Although the configuration of the thin film transistor 10 is described above, the thin film transistor 10 described above is a so-called top-gate transistor. The thin film transistor 10 can be modified in various ways. For example, when the light shielding layer 105 has conductivity, the thin film transistor 10 may have a structure in which the light shielding layer 105 functions as a gate electrode, and the first insulating layer 110 and the second insulating layer 120 function as gate insulating layers. In this case, the thin film transistor 10 is a so-called dual-gate transistor. Further, when the light shielding layer 105 has conductivity, the light shielding layer 105 may be a floating electrode and may be connected to the source electrode 201. Furthermore, the thin film transistor 10 may be a so-called bottom-gate transistor in which the light shielding layer 105 functions as a main gate electrode.

The above-described configuration of the thin film transistor 10 is merely an embodiment, and the present invention is not limited to the above-described configuration. Hereinafter, a configuration of a thin film transistor 10A, which is a modification of the thin film transistor 10, is described.

### Modification

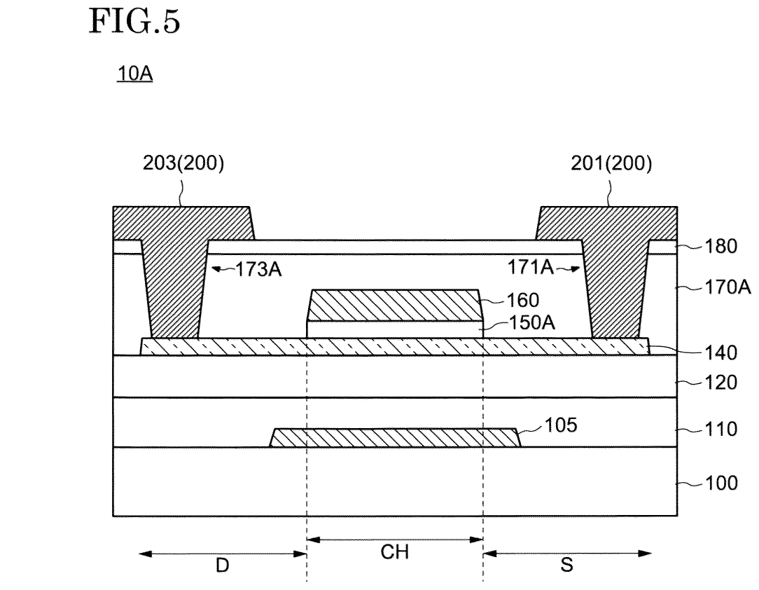

FIG. 5 is a schematic cross-sectional view showing the configuration of the thin film transistor 10A according to an embodiment of the present invention. When the configuration of the thin film transistor 10A is similar to that of the thin film transistor 10, the description of the configuration of the thin-film transistor 10A may be omitted.

As shown in FIG. 5, the thin film transistor 10A includes the substrate 100, the light shielding layer 105, the first insulating layer 110, the second insulating layer 120, the oxide semiconductor layer 140, a gate insulating layer 150A, the gate electrode 160, a third insulating layer 170A, the fourth insulating layer 180, the source electrode 201, and the drain electrode 203.

Although the gate insulating layer 150A is provided on the oxide semiconductor layer 140, a part of the oxide semiconductor layer 140 is exposed from the gate insulating layer 150A. The gate insulating layer 150A overlaps the gate electrode 160, and the edge portion of the gate insulating layer 150A is substantially aligned with the edge portion of the gate electrode 160. The third insulating layer 170A is provided on the second insulating layer 120 so as to cover the upper surface and the edge surface of the gate electrode 160, an edge surface of the gate insulating layer 150A, and the upper surface and the edge surface of the oxide semiconductor layer 140. The third insulating layer 170A and the fourth insulating layer 180 are provided with openings 171A and 173A through which a part of the upper surface of the oxide semiconductor layer 140 is exposed. The source electrode 201 is provided on the fourth insulating layer 180 and inside the opening 171A so as to be in contact with the oxide semiconductor layer 140. Similarly, the drain electrode 203 is provided on the fourth insulating layer 180 and inside the opening 173A so as to be in contact with the oxide semiconductor layer 140.

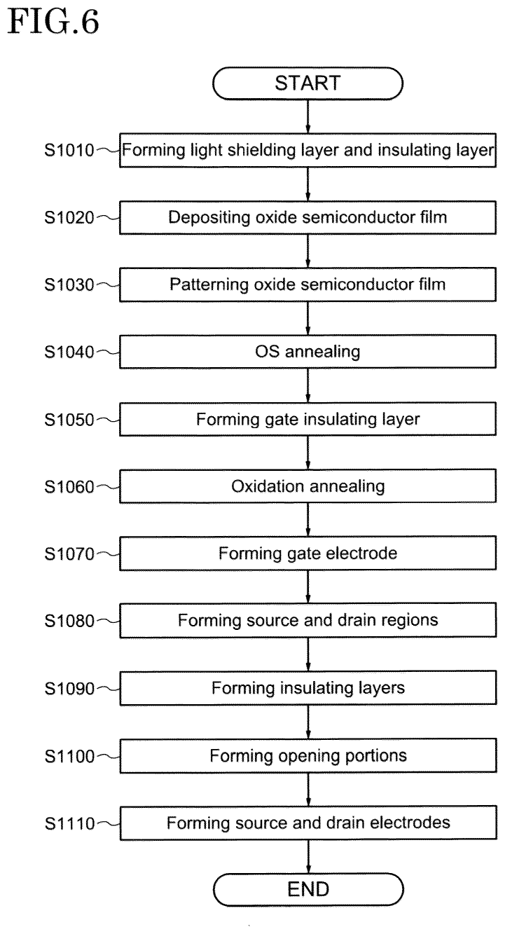

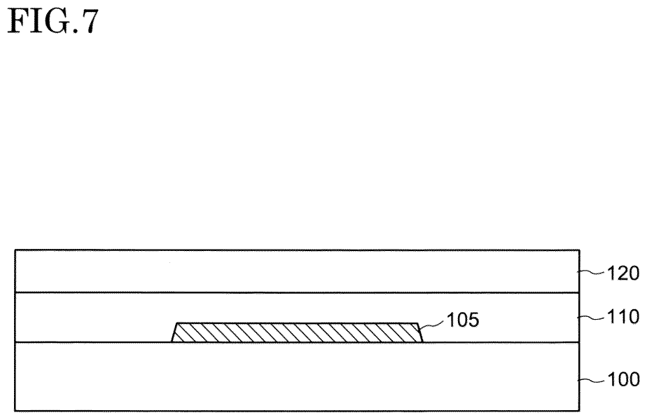

In the thin film transistor 10A, the oxide semiconductor layer 140 also includes the Poly-OS. Therefore, since diffusion of hydrogen in the oxide semiconductor layer 140 is suppressed, the penetration length ΔL of the third region 143 can be reduced.

[3. Method for Manufacturing Thin film transistor 10] A method for manufacturing the thin film transistor 10 according to an embodiment of the present invention is described with reference to FIGS. 6 to 13. FIG. 6 is a flowchart showing the method for manufacturing the thin film transistor 10 according to an embodiment of the present invention. FIGS. 7 to 13 are schematic cross-sectional views showing the method of manufacturing the thin film transistor 10 according to an embodiment of the present invention.

As shown in FIG. 6, the method for manufacturing the thin film transistor 10 includes steps S1010 to S1110. In the following description, although the steps S1010 to S1110 are described in order, the order of the steps may be interchanged in the method for manufacturing the thin film transistor 10. Further, the method for manufacturing the thin film transistor 10 may include additional steps.

In the step S1010, the light shielding layer 105 having a predetermined pattern is formed on the substrate 100. The patterning of the light shielding layer 105 is performed using a photolithography method. The first insulating layer 110 and the second insulating layer 120 are formed on the light shielding layer 105 (see FIG. 7). The first insulating layer 110 and the second insulating layer 120 are deposited using a CVD method. For example, silicon nitride and silicon oxide are deposited as the first insulating layer 110 and the second insulating layer 120, respectively. When silicon nitride is used for the first insulating layer 110, the first insulating layer 110 can block impurities that diffuse from the substrate 100 into the oxide semiconductor layer 140. When silicon oxide is used for the second insulating layer 120, the second insulating layer 120 can release oxygen by a heat treatment.

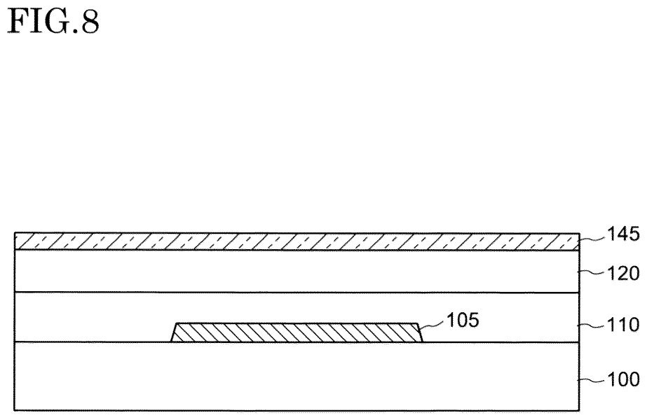

In the step S1020, an oxide semiconductor film 145 is formed on the second insulating layer 120 (see FIG. 8). The oxide semiconductor film 145 is deposited by a sputtering method. The thickness of the oxide semiconductor film 145 is, for example, greater than or equal to 10 nm and less than or equal to 100 nm, preferably greater than or equal to 15 nm and less than or equal to 70 nm, and more preferably greater than or equal to 20 nm and less than or equal to 40 nm.

The oxide semiconductor film 145 in the step S1020 is amorphous. In the Poly-OS technology, the oxide semiconductor film 145 after the deposition and before the heat treatment is preferably amorphous so that the oxide semiconductor layer 140 has a uniform polycrystalline structure in the substrate plane. Therefore, the deposition conditions of the oxide semiconductor film 145 are preferably conditions under which the oxide semiconductor layer 140 immediately after the deposition is not crystallized as much as possible. When the oxide semiconductor film 145 is formed by a sputtering method, the oxide semiconductor film 145 is deposited while controlling the temperature of the object to be deposited (the substrate 100 and the layers formed thereon) to less than or equal to 100° C. The oxygen partial pressure is greater than or equal to 2% and less than or equal to 20%, preferably greater than or equal to 3% and less than or equal to 15%, and more preferably greater than or equal to 3% and less than or equal to 10%.

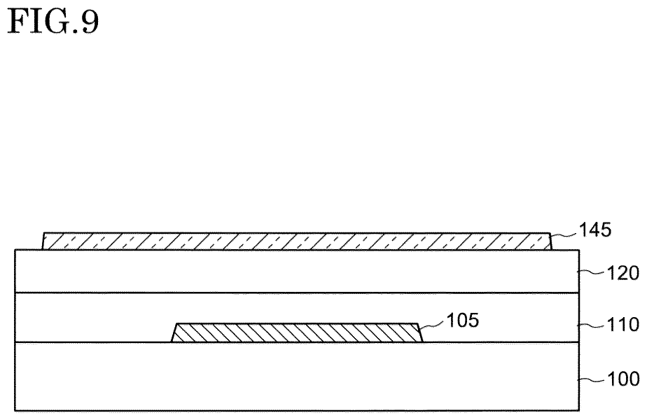

In the step S1030, the oxide semiconductor film 145 is patterned (see FIG. 9). The patterning of the oxide semiconductor film 145 is performed using a photolithography method. Wet etching or dry etching may be used for the etching of the oxide semiconductor film 145. The wet etching can be performed using an acidic etchant. For example, oxalic acid, PAN, sulfuric acid, hydrogen peroxide solution, hydrofluoric acid, or the like can be used for the etchant.

In the step S1040, a heat treatment is performed on the oxide semiconductor film 145. Hereinafter, the heat treatment performed in step S1040 is referred to as “OS annealing.” In the OS annealing, the oxide semiconductor film 145 is held at a predetermined reaching temperature for a predetermined time. The predetermined reaching temperature is higher than or equal to 300° C. and lower than or equal to 500° C., and preferably higher than or equal to 350° C. and lower than or equal to 450° C. The holding time at the reaching temperature is greater than or equal to 15 minutes and less than or equal to 120 minutes, and preferably greater than or equal to 30 minutes and less than or equal to 60 minutes. The oxide semiconductor film 145 is crystallized to form the oxide semiconductor layer 140 having a polycrystalline structure by the OS annealing.

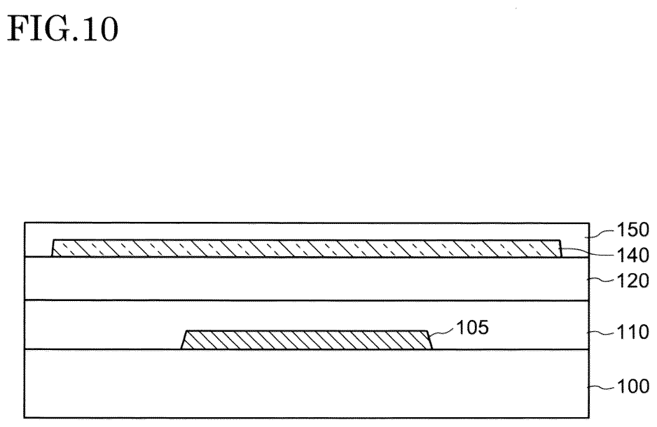

In the step S1050, the gate insulating layer 150 is formed on the oxide semiconductor layer 140 (see FIG. 10). The gate insulating layer 150 is deposited using a CVD method. For example, silicon oxide is deposited for the gate insulating layer 150. In order to reduce defects in the gate insulating layer 150, the gate insulating layer 150 may be deposited at a deposition temperature of higher than or equal to 350° C. The thickness of the gate insulating layer 150 is greater than or equal to 50 nm and less than or equal to 300 nm, preferably greater than or equal to 60 nm and less than or equal to 200 nm, and more preferably greater than or equal to 70 nm and less than or equal to 150 nm. After the gate insulating layer 150 is deposited, a treatment for introducing oxygen into a part of the gate insulating layer 150 may be performed.

In the step S1060, a heat treatment is performed on the oxide semiconductor layer 140. Hereinafter, the heat treatment performed in step S1060 is referred to as “oxidation annealing.” When the gate insulating layer 150 is formed on the oxide semiconductor layer 140, many oxygen vacancies are generated on the top surface and side surfaces of the oxide semiconductor layer 140. When oxidation annealing is performed, oxygen is supplied from the second insulating layer 120 and the gate insulating layer 150 to the oxide semiconductor layer 140, and oxygen vacancies are repaired.

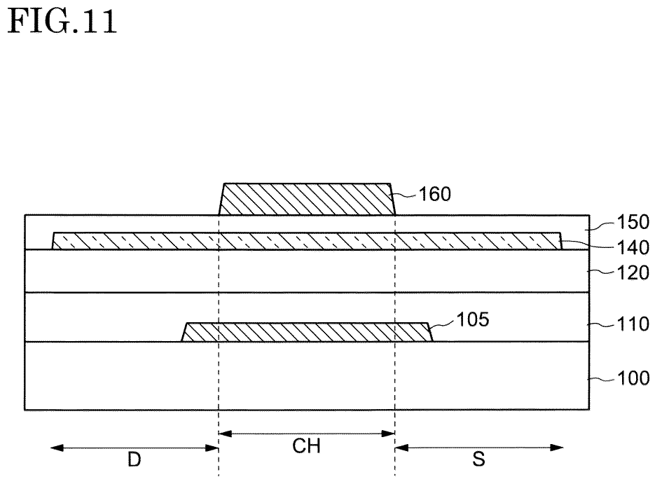

In the step S1070, the gate electrode 160 having a predetermined pattern is formed on the gate insulating layer 150 (see FIG. 11). The gate electrode 160 is deposited by a sputtering method or an atomic layer deposition method, and patterning of the gate electrode 160 is performed using a photolithography method.

In the step S1080, the source region S and the drain region D are formed in the oxide semiconductor layer 140 (see FIG. 11). The source region S and the drain region D are formed by ion implantation. Specifically, impurities are implanted into the oxide semiconductor layer 140 through the gate insulating layer 150 using the gate electrode 160 as a mask. For example, argon (Ar), phosphorus (P), boron (B), or the like is used as the implanted impurity. Oxygen deficiencies are generated by the ion implantation in the source region S and the drain region D that do not overlap the gate electrode 160, so that the resistance of the source region S and the drain region D is lowered. On the other hand, since no impurities are implanted in the channel region CH that overlaps the gate electrode 160, the resistance of the channel region CH is not lowered. Further, hydrogen is trapped in the source region S and the drain region D due to oxygen deficiencies generated in the source region S and the drain region D. Furthermore, the Poly-OS included in the oxide semiconductor layer 140 has a small diffusion coefficient of hydrogen. Therefore, the diffusion of hydrogen from the source region S or the drain region D to the edge portion of the channel region CH is suppressed. Accordingly, the penetration depth ΔL of the third region 143 can be reduced.

In addition, in the thin film transistor 10, since impurities are implanted into the oxide semiconductor layer 140 through the gate insulating layer 150, impurities such as argon (Ar), phosphorus (P), boron (B), or the like are included in the gate insulating layer 150.

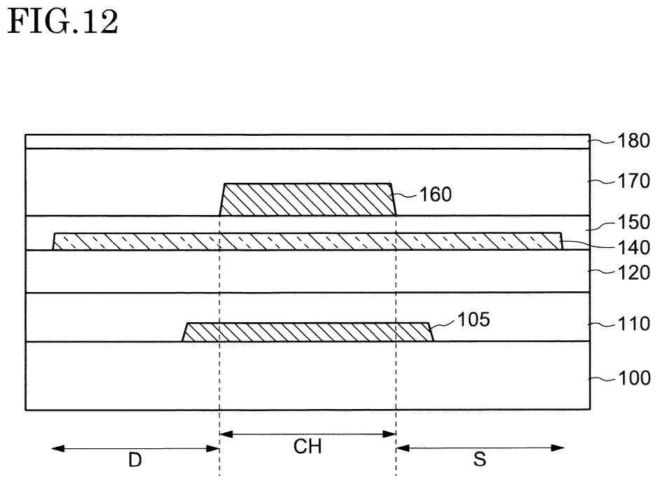

In the step S1090, the third insulating layer 170 and the fourth insulating layer 180 are formed over the gate insulating layer 150 and the gate electrode 160 (see FIG. 12). The third insulating layer 170 and the fourth insulating layer 180 are deposited using a CVD method. For example, silicon oxide and silicon nitride are deposited for the third insulating layer 170 and the fourth insulating layer 180, respectively. The thickness of the third insulating layer 170 is greater than or equal to 50 nm and less than or equal to 500 nm. The thickness of the fourth insulating layer 180 is also greater than or equal to 50 nm and less than or equal to 500 nm.

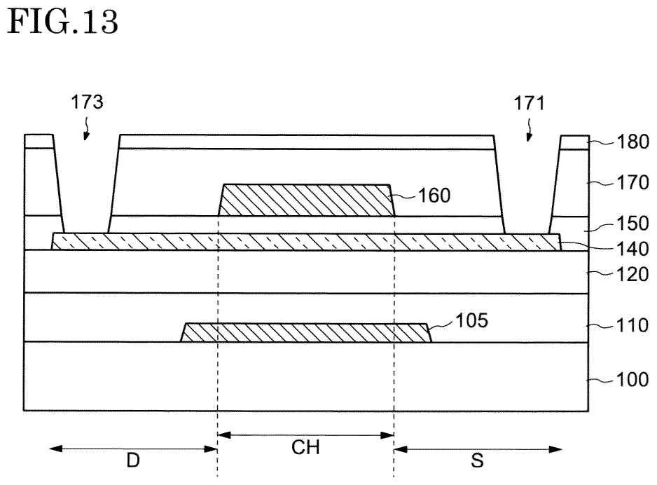

In the step S1100, the opening portions 171 and 173 are formed in the gate insulating layer 150, the third insulating layer 170, and the fourth insulating layer 180 (see FIG. 13). The source region S and the drain region D of the oxide semiconductor layer 140 is exposed by the formation of the opening portions 171 and 173.

In the step S1110, the source electrode 201 is formed on the fourth insulating layer 180 and inside the opening portion 171, and the drain electrode 203 is formed on the fourth insulating layer 180 and inside the opening portion 173. The source electrode 201 and the drain electrode 203 are formed as the same layer. Specifically, the source electrode 201 and the drain electrode 203 are formed by patterning one deposited conductive film. The thin film transistor 10 shown in FIG. 1 is manufactured through the above steps.

Although the method for manufacturing the thin film transistor 10 is described above, various manufacturing methods are possible depending on the structure of the thin film transistor 10. For example, in the thin film transistor 10A described as the modification of the thin film transistor 10, the gate insulating layer 150A may be patterned using the gate electrode 160 as a mask so that the upper surface and the edge surface of the oxide semiconductor layer 140 are exposed. Then, when a plasma treatment using argon, helium, nitrogen, a fluorine-based gas, or the like is performed on the exposed oxide semiconductor layer 140, the source region S and the drain region D with reduced resistance can be formed. Next, the third insulating layer 170A is formed so as to cover the source region S and the drain region D. Even in this case, oxygen deficiencies in the source region S and the drain region D trap hydrogen. Further, the oxide semiconductor layer 140 includes the Poly-OS. Therefore, since the diffusion of hydrogen from the source region S or the drain region D to the edge portion of the channel region CH is suppressed, the penetration length ΔL of the third region 143 can be reduced.

In the thin film transistor 10 according to the present embodiment, since the oxide semiconductor layer 140 includes the Poly-OS, the diffusion of hydrogen from the source region S and the drain region D is suppressed, and the penetration length ΔL in the channel region CH is reduced. As a result, the effective channel length L_{eff} can be increased, and thus the shift and variation in the threshold voltage with respect to the channel length L in the thin film transistor 10 can be suppressed. For example, even in the case of the thin film transistor 10 having a channel length L of 2 μm, excellent electrical characteristics can be obtained. Therefore, the thin film transistor 10 has a high degree of freedom in designing the channel length, and can be applied to various electronic devices or electric devices.

### Second Embodiment

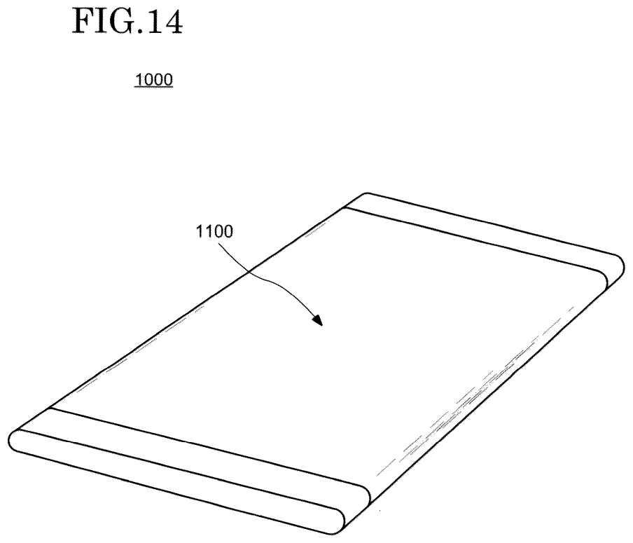

An electronic device according to an embodiment of the present embodiment is described with reference to FIG. 14.

FIG. 14 is a schematic diagram showing an electronic device 1000 according to an embodiment of the present embodiment. Specifically, FIG. 14 shows a smartphone, which is an example of the electronic device 1000. The electronic device 1000 includes a display device 1100 with curved sides. The display device 1100 includes a plurality of pixels for displaying an image. The plurality of pixels are controlled by a pixel circuit, a drive circuit, and the like.

The pixel circuit and the drive circuit include the thin film transistor 10 described in the First Embodiment. Since the thin film transistor 10 has high field effect mobility, the responsiveness of the pixel circuit and the drive circuit can be improved, and as a result, the performance of the electronic device 1000 can be improved.

In addition, the electronic device 1000 according to the present embodiment is not limited to a smartphone. For example, the electronic device 1000 also includes an electronic device having a display device, such as a watch, a tablet, a notebook computer, a car navigation system, or a television. The oxide semiconductor film described in the First Embodiment or the thin film transistor 10 described in the First Embodiment can be applied to any electronic device, regardless of whether or not the electronic device has a display device.

### Example

The thin film transistor 10 is described in more detail based on the fabricated samples. The example described below is one example of the thin film transistor 10, and the configuration of the thin film transistor 10 is not limited to the configuration of the example described below.

### [1. Difference in Crystallinity of Oxide Semiconductor Layer]

### [1-1. Fabrication of Samples for Electrical Characteristics]

The thin film transistor 10 which corresponded to a sample of the example (hereinafter, referred to as “Example Sample 1”) was fabricated using the manufacturing method described in the First Embodiment. In the Example Sample 1, an oxide semiconductor containing indium at an atomic ratio greater than or equal to 70% with respect to all metal elements was used as a sputtering target for forming the oxide semiconductor layer 140. Although the oxide semiconductor layer 140 in the Example Sample 1 had an amorphous structure before the OS annealing, the oxide semiconductor layer 140 was crystallized by the OS annealing to have a polycrystalline structure. That is, the Example Sample 1 is the thin film transistor 10 including the Poly-OS.

A thin film transistor which corresponded to a comparative sample (hereinafter, referred to as “Comparative Sample 1”) was fabricated using indium gallium zinc oxide (IGZO) in which the ratio of indium was less than 50% for an oxide semiconductor layer. The oxide semiconductor layer in the Comparative Sample 1 had an amorphous structure before and after the OS annealing. The Comparative Sample 1 had the same structure as the Example Sample 1 except for the oxide semiconductor layer.

### [1-2. Electrical Characteristics]

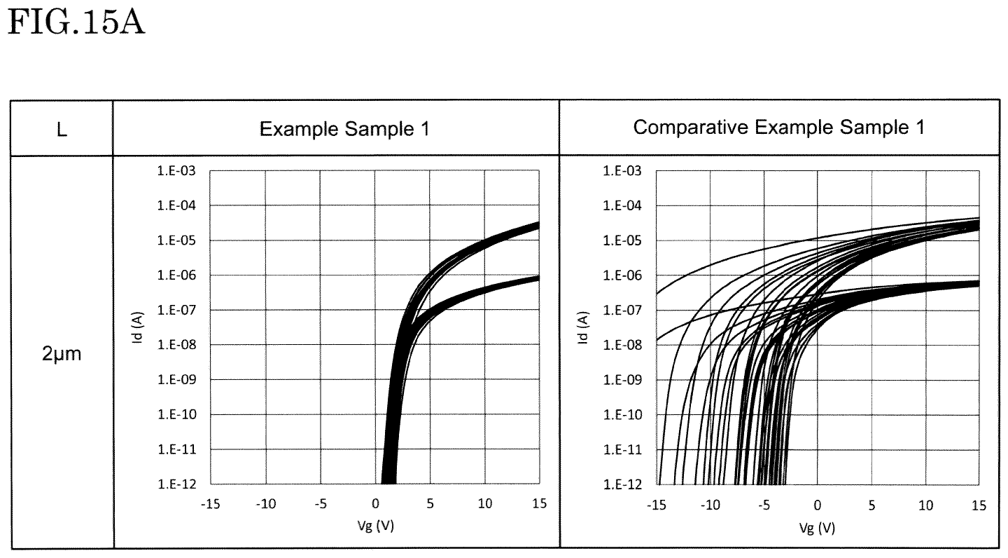

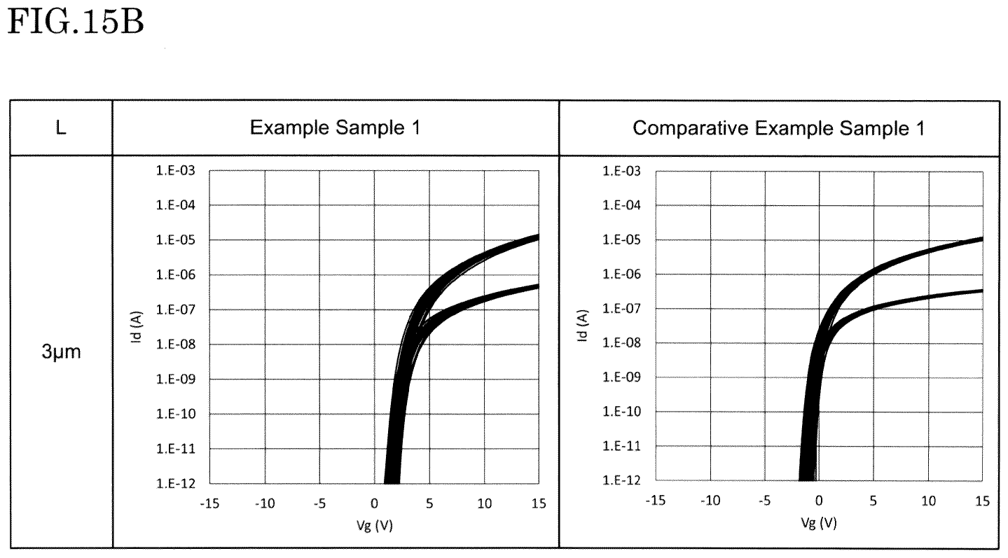

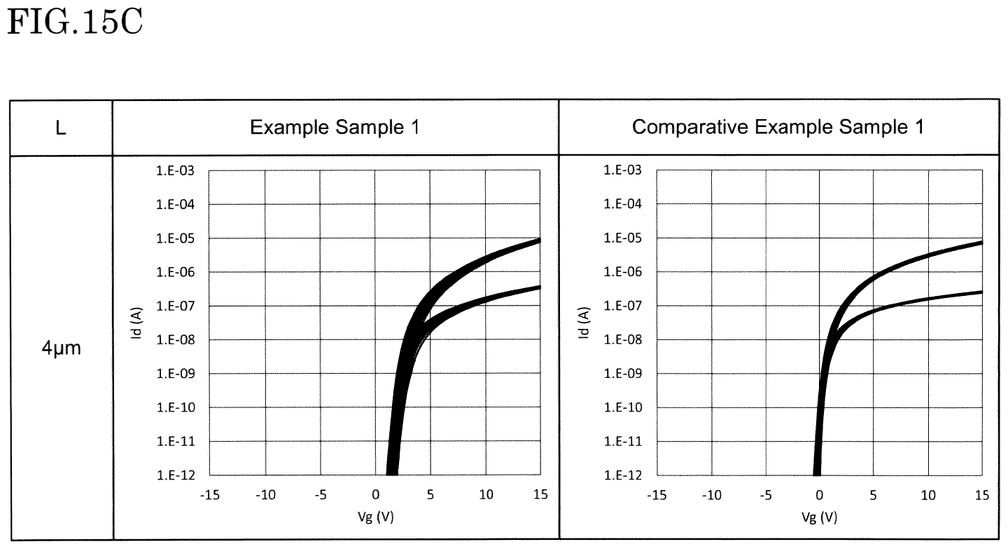

FIGS. 15A to 15C are graphs showing electrical characteristics of the Example Sample 1 and the Comparative Example Sample 1. FIGS. 15A to 15C show the electrical characteristics of a plurality of thin film transistors having a channel width W of 7.5 μm and a channel length L of 2 μm, 3 μm, and 4 μm in each of the Example Sample 1 and the Comparative Example Sample 1. The vertical axis of each graph represents a drain current Id, and the horizontal axis represents a gate voltage Vg. The measurement conditions of the electrical characteristics are as shown in Table 1. Further, each graph includes the electrical characteristics measured for 18 thin film transistors (i.e., N=18).

TABLE 1

| | 0.1 V (dotted line), |
|---|---|
| Source-Drain voltage | 10 V (solid line) |
| Gate Voltage | −15 V to +15 V |
| Measurement | Room temperature, |
| Environment | dark room |

In the Example Sample 1, good electrical characteristics were obtained for all of the thin film transistors 10 having channel lengths L of 2 μm, 3 μm, and 4 μm. That is, the Example Sample 1 showed a small shift and variation in threshold voltage with respect to channel length L. On the other hand, in the Comparative Example Sample 1, when the channel length L became smaller, the threshold voltage shifted in the negative direction, and the electrical characteristics of the thin film transistor having a channel length L of 2 μm showed a very large variation in threshold voltage.

According to the results of the electrical characteristics of the Example Sample 1 and the Comparative Sample 1, it is considered that the oxide semiconductor layer 140 includes the Poly-OS, so that the diffusion of hydrogen from the source region S and the drain region D to the channel region CH is suppressed. Therefore, a TDS measurement was performed to examine the difference in the diffusion coefficient of hydrogen between the Poly-OS and amorphous IGZO. Hereinafter, the TDS measurement is described.

### [1-3. Fabrication of Samples for TDS Measurement]

A sample having the Poly-OS (thickness of 50 nm) formed on a silicon substrate (hereinafter, referred to as “Example Sample 2”) was fabricated for a TDS measurement of the example. Further, a sample having amorphous IGZO (thickness of 50 nm) formed on a silicon substrate (hereinafter, referred to as “comparative example sample 2”) was fabricated for a TDS measurement of the comparative example.

### [1-4. TDS Measurement]

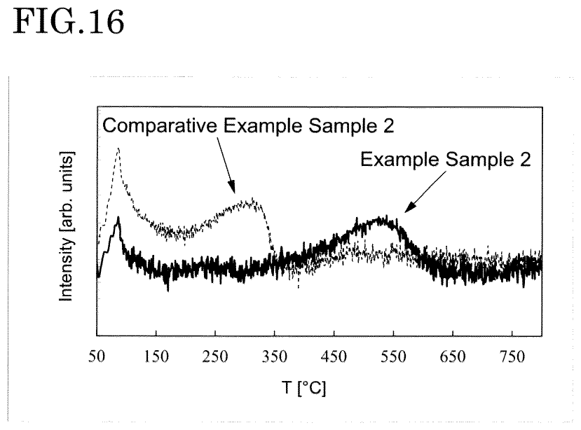

FIG. 16 is a graph showing results of a TDS measurement for the Example Sample 2 and the Comparative Example Sample 2. FIG. 16 shows the temperature profile of molecular weight 18 at a temperature rise rate of 10° C./min. The temperature T of the horizontal axis in the graph is the temperature of the stage.

As shown in FIG. 16, a peak is observed near 530° C. in the Example Sample 2 (solid line in FIG. 16). On the other hand, a peak is observed near 310° C. in the Comparative Example Sample 2 (dotted line in FIG. 16). Since the molecular weight of 18 corresponds to water (H₂O), it is considered that the temperature profile shown in FIG. 16 is caused by water desorbed from the Poly-OS or amorphous IGZO. Here, the water detected by the TDS measurement includes not only water adsorbed in the Poly-OS or amorphous IGZO but also water generated by an oxygen reaction with hydrogen contained and diffused in the Poly-OS or amorphous IGZO. It is difficult to distinguish whether the peak detected in the temperature profile is caused by the former or the latter. However, when hydrogen is difficult to diffuse, it is difficult to react with oxygen, so that it is considered that the generation of water in the latter is suppressed.

The peak temperature of the Example Sample 2 is higher than that of the Comparative Sample 2. This means that hydrogen is less likely to diffuse in the Poly-OS of the Example Sample 2, and therefore a higher temperature is required to diffuse hydrogen. In other words, since it is considered that hydrogen is less likely to diffuse in the Poly-OS than in amorphous IGZO, the peak temperature of the Example Sample 2 is shifted to a higher temperature than that of the Comparative Sample 2. Therefore, it can be said that an oxide semiconductor having a polycrystalline structure such as the Poly-OS of the Example Sample 2 has a smaller diffusion coefficient of hydrogen than an oxide semiconductor having an amorphous structure such as the amorphous IGZO of the Comparative Sample 2.

According to the results of the electrical characteristics and the TDS measurements as described above, it can be considered that the oxide semiconductor layer 140 having a polycrystalline structure suppresses hydrogen diffusion more than the oxide semiconductor layer having an amorphous structure. Therefore, the diffusion of hydrogen from the source region S or the drain region D to the channel region CH is suppressed in the Example Sample 1. As a result, good electrical characteristics can be obtained even in a thin film transistor having a short channel length in the Example Sample 1.

### [2. Difference in Manufacturing Process Conditions]

### [2-1. Fabrication of Samples for SCM Observation]

The Example Sample 1 was used for the SCM observation of the example. Further, the thin film transistor 10A described as the modification of the First Embodiment (hereinafter, referred to as “Example Sample 3”) was fabricated for the SCM observation of the example with a different manufacturing process condition. The oxide semiconductor layer 140 of the thin film transistor 10A also includes the Poly-OS. However, in the Example Sample 1, ions were implanted into the oxide semiconductor layer 140 through the gate insulating layer 150 to form the source region S and the drain region D, whereas in Example Sample 3, a plasma treatment was directly performed on the oxide semiconductor layer 140 exposed from the gate insulating layer 150A to form the source region S and the drain region D.

### [2-2. SCM Observation]

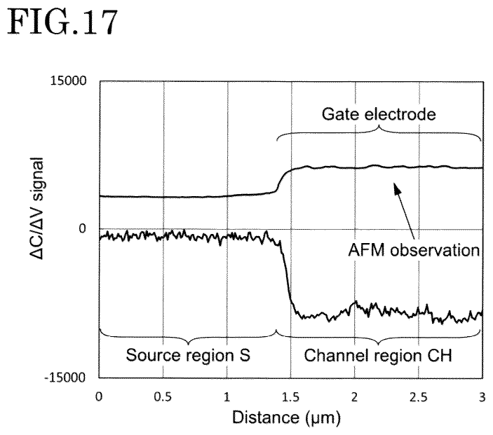

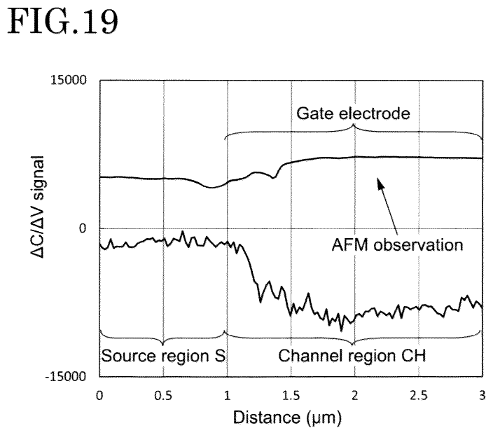

FIGS. 17 and 19 are graphs showing results of an SCM observation of the Example Sample 1 and the Example Sample 3, respectively. Each of FIGS. 17 and 19 shows not only a ΔC/ΔV signal obtained by the SCM observation but also a profile (arbitrary units) in an AFM observation. The apparatus and conditions for the SCM observation are as shown in Table 2.

TABLE 2

| | |
|---|---|
| Apparatus | Bruker Dimension 3100 |
| SCM probe | PtIr coated silicon cantilever |
| Modulation Voltage | 2.0 V |
| DC Bias Voltage | 0 V |

As shown in each of FIGS. 17 and 19, it was found that the edge portion of the gate electrode 160 obtained by the AFM observation and the edge portion of the channel region CH obtained by the SCM observation were substantially aligned with each other.

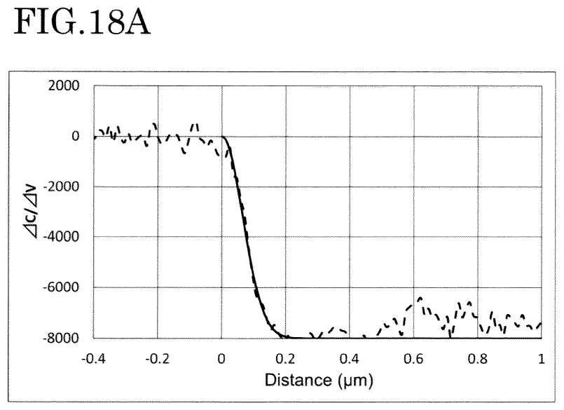

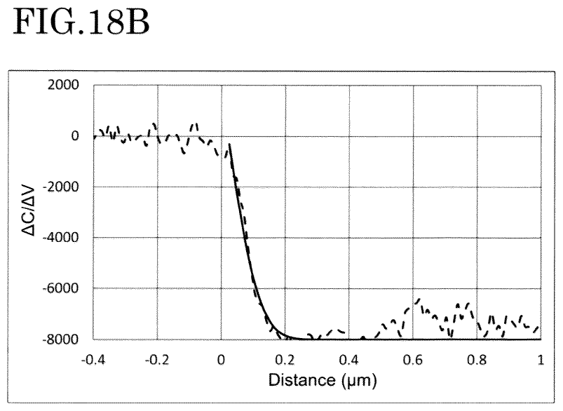

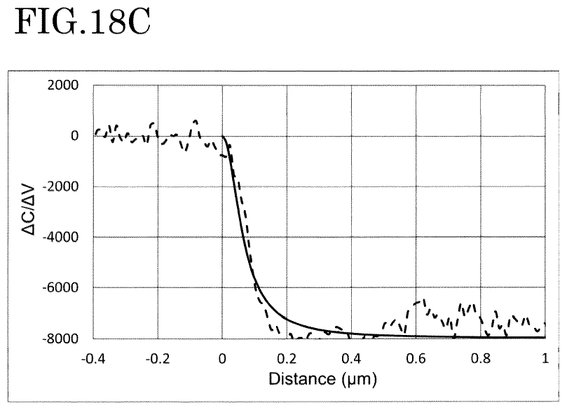

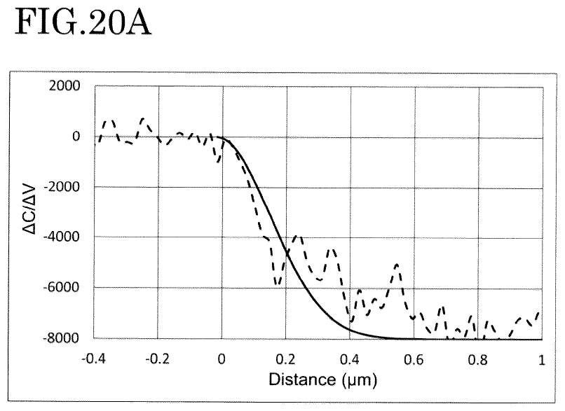

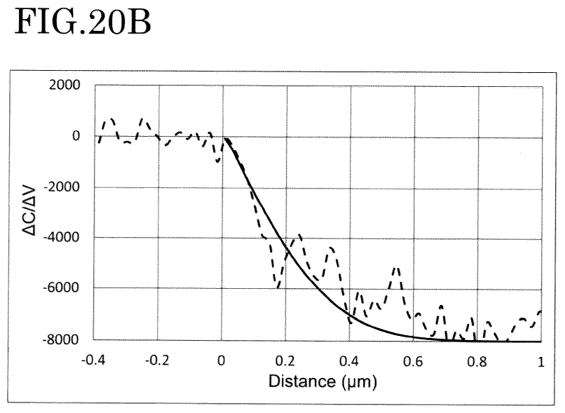

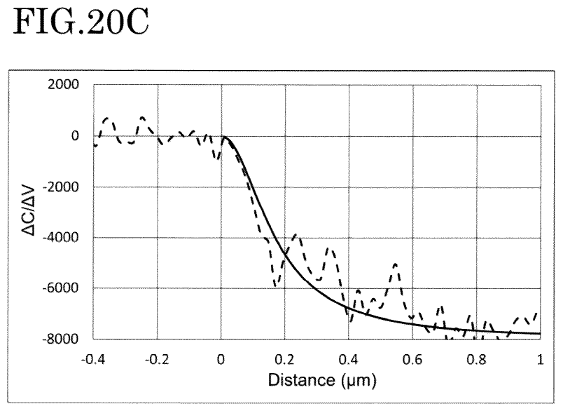

FIGS. 18A, 18B, and 18C are graphs obtained by fitting the ΔC/ΔV signal obtained by the SCM observation of the Example Sample 1 with a Gaussian function, a complementary error function, and a Lorentz function. Further, FIGS. 20A, 20B, and 20C are graphs obtained by fitting the ΔC/ΔV signal obtained by the SCM observation of the Example Sample 3 with a Gaussian function, a complementary error function, and a Lorentz function. In FIGS. 18A to 18C and 20A to 20C, the ΔC/ΔV signal obtained by the SCM observation and the fitting function are shown by a dotted line and a solid line, respectively. Furthermore, when the fitting function was fitted, the distance was corrected so that the edge portion of the gate electrode 160 was the origin. The positive direction of the distance is the direction overlapping the gate electrode 160, and the negative direction of the distance is the direction not overlapping the gate electrode 160.

Table 3 shows the values c calculated by fitting the ΔC/ΔV signal using each fitting function. Table 4 shows the penetration depth ΔL converted from the calculated value c based on ΔL=3c.

TABLE 3

| | Value c in fitting function | | |
|---|---|---|---|
| | Gaussian | Complementary | Lorentz |
| | function | error function | function |
| Example Sample 1 | 0.065 μm | 0.055 μm | 0.065 μm |
| Example Sample 3 | 0.17 μm | 0.18 μm | 0.17 μm |

TABLE 4

| | Penetration Depth ΔL converted from Value c | | |
|---|---|---|---|
| | Gaussian | Complementary | Lorentz |
| | function | error function | function |
| Example Sample 1 | 0.20 μm | 0.17 μm | 0.20 μm |
| Example Sample 3 | 0.51 μm | 0.54 μm | 0.51 μm |

As shown in Table 4, regardless of which fitting function is used, the penetration length ΔL of the Example Sample 1 is about 0.20 μm, and the penetration length ΔL of the Example Sample 3 is about 0.50 μm. As can be seen from this result, the penetration length ΔL can be controlled to be less than or equal to 0.60 μm in the oxide semiconductor layer 140 including the Poly-OS. In particular, regardless of which fitting function was used, the penetration length ΔL can be controlled to be less than or equal to 0.30 μm in the Example Sample 1.

According to the results of the SCM observation as described above, even when the oxide semiconductor layer 140 has a polycrystalline structure, it is found that the penetration length ΔL of the third region 143 varies depending on the process conditions for forming the source region S and the drain region D of the thin film transistor 10. In particular, in the thin film transistor 10 including the Poly-OS, it is found that when ions are implanted into the oxide semiconductor layer 140 through the gate insulating layer 150 to form the source region S and the drain region D, as described in the First Embodiment with reference to the flowchart of FIG. 6, the penetration length ΔL of the third region 143 becomes smaller. Therefore, the method for manufacturing the thin film transistor 10 by implanting ions into the oxide semiconductor layer 140 through the gate insulating layer 150 is an effective method for controlling the diffusion of hydrogen from the source region S and the drain region D in the Poly-OS so as to be further suppressed. As a result, the thin film transistor 10 has excellent electrical characteristics even in the case of the thin film transistor 10 having a channel length L of 2 μm. Therefore, the thin film transistor 10 has a high degree of freedom in designing the channel length and can be applied to various electronic devices or electric devices.

Each of the embodiments described above as an embodiment of the present invention can be appropriately combined and implemented as long as no contradiction is caused. Further, the addition, deletion, or design change of components, or the addition, deletion, or condition change of processes as appropriate by those skilled in the art based on each of embodiments are included in the scope of the present invention as long as they are provided with the gist of the present invention.

It is understood that, even if the effect is different from those provided by each of the above-described embodiments, the effect obvious from the description in the specification or easily predicted by persons ordinarily skilled in the art is apparently derived from the present invention.

What is claimed is:

1. A thin film transistor, comprising:
an oxide semiconductor layer having a polycrystalline structure over a substrate;
a gate electrode over the oxide semiconductor layer; and
a gate insulating layer between the oxide semiconductor layer and the gate electrode,
wherein the oxide semiconductor layer comprises:
a first region having a first carrier concentration, the first region overlapping the gate electrode,
a second region having a second carrier concentration, the second region not overlapping the gate electrode, and
a third region between the first region and the second region, the third region overlapping the gate electrode,
wherein the second carrier concentration is larger than the first carrier concentration,
wherein a carrier concentration of the third region decreases from the second region to the first region in a channel length direction, and
wherein a length of the third region is less than or equal to 0.60 μm in the channel length direction.

2. The thin film transistor according to claim 1, wherein the length of the third region is less than or equal to 0.50 μm.

3. The thin film transistor according to claim 1, wherein the length of the third region is less than or equal to 0.40 μm.

4. The thin film transistor according to claim 1,
wherein the length of the third region is three times a scale parameter calculated from a Gaussian function with which a ΔC/ΔV signal obtained by scanning capacitance microscopy observation is fitted, and
wherein ΔC and ΔV are a capacitance change and an ΔC voltage, respectively.

5. The thin film transistor according to claim 1,
wherein the length of the third region is three times a scale parameter calculated from a complementary error function with which a ΔC/ΔV signal obtained by scanning capacitance microscopy observation is fitted, and
wherein ΔC and ΔV are a capacitance change and an ΔC voltage, respectively.

6. The thin film transistor according to claim 1,
wherein the length of the third region is three times a scale parameter calculated from a Lorentzian function with which a ΔC/ΔV signal obtained by scanning capacitance microscopy observation is fitted, and
wherein ΔC and ΔV are a capacitance change and an ΔC voltage, respectively.

7. The thin film transistor according to claim 1, wherein the second region comprises at least one of boron, phosphorous, and argon.

8. The thin film transistor according to claim 1, wherein an edge portion is covered with the gate insulating layer.

9. The thin film transistor according to claim 8, wherein the gate insulating layer comprises at least one of boron, phosphorous, and argon.

10. The thin film transistor according to claim 1,
wherein the oxide semiconductor layer comprises indium and at least one or more metal elements, and
wherein a ratio of the indium with respect to the indium and the at least one or more metal elements is greater than or equal to 50%.

11. The thin film transistor according to claim 1, wherein a crystal structure of the oxide semiconductor layer is a bixbyite structure.

12. An electronic device comprising the thin film transistor according to claim 1.
